(19) United States
(12) Patent Application Publication
(10) Pub. No.: US 2024/0405509 A1
(43) Pub. Date: Dec. 5, 2024

(54) SEMICONDUCTOR DEVICE

(71) Applicant: EPISTAR CORPORATION, Hsinchu (TW)

(72) Inventor: Shih-Chun LING, Hsinchu (TW)

(21) Appl. No.: 18/677,007

(22) Filed: May 29, 2024

(30) Foreign Application Priority Data
May 30, 2023 (TW) 112120165

(51) Int. Cl. H01S 5/042; H01S 5/02212; H01S 5/223

(52) U.S. Cl. CPC H01S 5/04256; H01S 5/02212; H01S 5/04254; H01S 5/223

(57) ABSTRACT

A semiconductor device includes a substrate, an epitaxial structure and a first interlayer. The substrate has an upper surface and a bottom surface. The epitaxial structure is on the upper surface and includes an active structure. The first interlayer is on the bottom surface and includes M1x1Ny1. M1 is metal and N is nitrogen, and x1>y1.

### BACKGROUND

### Technical Field

The present disclosure relates to semiconductor device, and in particular to a laser semiconductor device.

### Description of the Related Art

Recently, the demand for semiconductor light-emitting devices is increasing, and the light-emitting devices may include laser semiconductors. In the structure of laser semiconductors, the contact characteristics between metal and semiconductor are susceptible to failure problems due to subsequent high-temperature processes, thereby affecting their optoelectronic properties. Therefore, there is still a need for an improved semiconductor light-emitting element to improve the contact characteristics between metal and semiconductor so that the optoelectronic characteristics of laser semiconductors meet application requirements.

### BRIEF SUMMARY

A semiconductor device includes a substrate, an epitaxial structure and a first interlayer. The substrate has an upper surface and a bottom surface. The epitaxial structure is on the upper surface and includes an active structure. The first interlayer is on the bottom surface and includes M1ₓ₁N_{y1}. M1 is metal and N is nitrogen, and x1>y1.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1A illustrates a top-view of a semiconductor device in accordance with one embodiment of the present disclosure.

FIG. 1B illustrates a cross-sectional view of a semiconductor device in accordance with one embodiment of the present disclosure.

FIG. 2 illustrates a cross-sectional view of a semiconductor device in accordance with one embodiment of the present disclosure.

FIG. 3 illustrates a cross-sectional view of a semiconductor apparatus in accordance with an embodiment of the present disclosure.

### DETAILED DESCRIPTION

In order to make the description of the present disclosure more detailed and complete, the present disclosure will be described in detail below with reference to the drawings. It should be noted that the following is used to illustrate the embodiments of the semiconductor device of the present disclosure and does not limit the present disclosure in the following embodiments. In the drawings or descriptions, similar or identical components will be described with similar or identical numbers, and unless otherwise specified, the shape or size of each element in the drawings is only for illustration and is not actually limited thereto. It should be noted that components not shown or described in the drawings may be in forms known by the person having ordinary skill in the art.

In addition, unless otherwise specified, a similar description of “the first layer (or structure) is located on the second layer (or structure)” may indicate that the first layer (or structure) directly contacts the second layer (or structure), or other layers or structures is disposed between the first layer (or structure) and the second layer (or structure) so the first layer does not directly contact the second layer. In addition, the upper and lower positions of each layer (or structure) may change based on the observation from different directions. For clarity of explanation, reference may be made to the coordinate axes (such as horizontal direction X or Y, vertical direction Z) marked in each figure for the following description of each embodiment. The horizontal direction X and the horizontal direction Y are perpendicular to each other.

The semiconductor device of the present disclosure may include a light-emitting chip (such as light-emitting diode or laser diode), a light-absorbing chip (such as photodetector or solar cell), or a non-light-emitting chip (such as switch or power components of rectifier). The laser diode can be an edge emitting laser (EEL), a vertical cavity surface emitting laser (VCSEL), or a photonic crystal surface emitting laser (PCSEL).

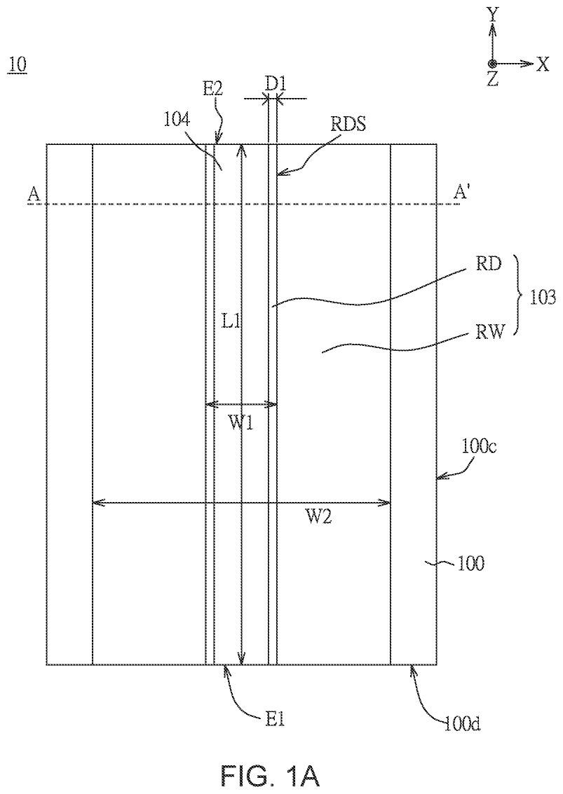

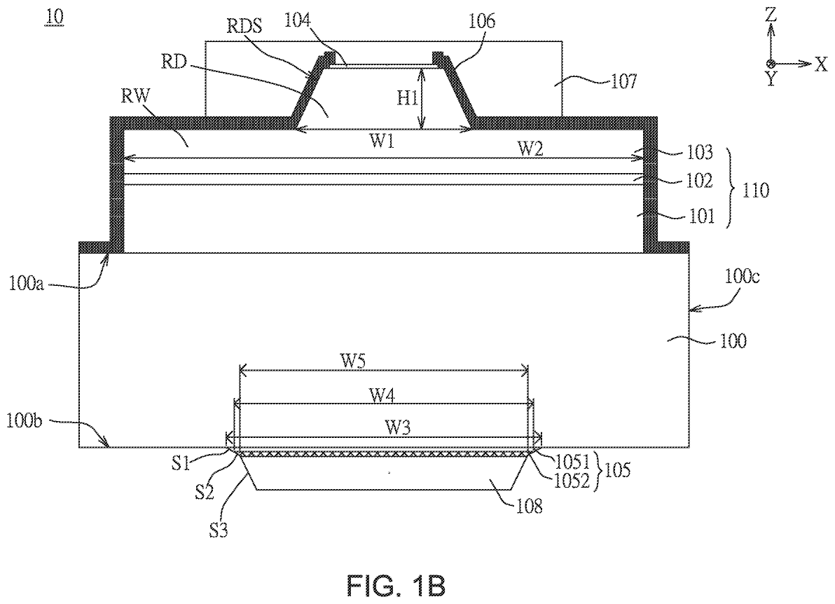

FIG. 1A is a schematic top view of a semiconductor device 10 according to an embodiment of the present disclosure. FIG. 1B shows a schematic cross-sectional view along section line A-A′ in FIG. 1A. FIG. 1A shows only some elements of the semiconductor device 10. As shown in FIGS. 1A and 1B, the semiconductor device 10 includes a substrate 100, an epitaxial stack 110, a contact structure 104, an intermediate structure 105, a protective structure 106, an upper electrode structure 107 and a lower electrode structure 108. The substrate 100 includes an upper surface 100a, a bottom surface 100b, a first edge 100c and a second edge 100d. In this embodiment, the substrate 100 is a rectangle. The first edge 100c is defined as the long side of the substrate 100, the second edge 100d is defined as the short side of the substrate 100, and the first edge 100c is perpendicular and connecting to the second edge 100d.

The epitaxial stack 110 is located on the upper surface 100a and includes a first semiconductor structure 101, an active structure 102 and a second semiconductor structure 103. The active structure 102 is located between the first semiconductor structure 101 and the second semiconductor structure 103. The first semiconductor structure 101 and the second semiconductor structure 103 have different conductive types. The first semiconductor structure 101 may include an n-type semiconductor structure and the second semiconductor structure 103 may include a p-type semiconductor structure, or the second semiconductor structure 103 may include an n-type semiconductor structure and the first semiconductor structure 101 may include a p-type semiconductor structure. The p-type semiconductor structure is, for example, a semiconductor structure doped with elements such as magnesium (Mg), lithium (Li), sodium (Na), potassium (K), beryllium (Be), zinc (Zn), or calcium (Ca). The n-type semiconductor structure is, for example, a semiconductor structure doped with elements such as silicon (Si), carbon (C), germanium (Ge), tin (Sn), lead (Pb), or oxygen (O). When the semiconductor device 10 is a semiconductor light-emitting device, the first semiconductor structure 101 and the second semiconductor structure 103 can provide electrons and holes or holes and electrons to the active structure 102 respectively. The electrons and holes can be combined in the active structure 102 to emit a light with specific wavelength. The light may include visible light or invisible light. Specifically, the epitaxial stack 110 may include a double heterostructure (DH), a double-side double heterostructure (DDH) or a multiple quantum wells (MQW) structure.

The light emitted by the semiconductor device 10 is determined by the material of the active structure 102. For example, when the material of the active structure 102 includes AlGaN, it can emit ultraviolet light with a peak wavelength of 250 nm to 400 nm; when the material of the active structure 102 includes InGaN, it can emit ultraviolet light with a peak wavelength of 400 nm to 490 nm, or deep blue light or blue light with a peak wavelength of 490 nm to 550 nm, or green light or yellow light with a peak wavelength of 490 nm to 550 nm, or red light with a peak wavelength of 560 nm to 650 nm; when the material of the active structure 102 includes InGaP or AlGaInP, it can emit yellow, orange or red light with a peak wavelength of 530 nm to 700 nm; when the material of the active structure 102 includes InGaAs, InGaAsP, AlGaAs or AlGaInAs, it can emit infrared light with a peak wavelength of 700 nm to 1700 nm.

As shown in FIGS. 1A and 1B, the second semiconductor structure 103 includes a ridge portion RD and a wider portion RW. The ridge portion RD is farther away from the active structure 102 than the wider portion RW. As shown in FIG. 1A, the ridge portion RD is arranged in a rectangular shape extending along the first edge 100c (that is, along the long side direction or the Y direction) of the substrate 100. The ridge portion RD has a first width W1 (along X direction), the wider portion RW has a second width W2, and the second width W2 is larger than the first width W1. The first width W1 may be between 1 μm and 100 μm, such as 10 μm, 20 μm, 50 μm, 80 μm, and 90 μm. The ridge portion RD further has a first length L1 (along Y direction) and a first height H1 (along Z direction). The first length L1 can be between 100 μm and 2000 μm, such as 400 μm, 800 μm, 1000 μm, and 1500 μm; the first height H1 can be between 100 nm˜900 nm, such as 200 nm, 500 nm, 800 nm.

The semiconductor device 10 of the present disclosure may be a laser diode and further includes a first end face E1 and a second end face E2, the first end face E1 and the second end face E2 perpendicular to the length direction (that is, the first edge 100c of the substrate 100) of the ridge portion RD. In one embodiment, a low-reflectivity structure (not shown) including a dielectric material is formed on the first end face E1, and a high-reflectivity structure (not shown) including a dielectric material is formed on the second end face E2. Therefore, the light generated from the active structure 102 can resonate back and forth between the first end face E1 and the second end face E2, and finally the light is emitted from the first end face E1. In other words, the first end face E1 can be defined as the light emitting surface, the second end face E2 can be defined as the reflecting surface, and the first end face E1 and the second end face E2 together form a resonant cavity.

The low reflectivity structure can be a single layer or multiple layers and the high reflectivity structure can be multiple layers. The dielectric material includes oxide, nitride or nitrogen oxide of aluminum (Al), silicon (Si), niobium (Nb), titanium (Ti), zirconium (Zr), hafnium (H), tantalum (Ta), zinc (Zn), yttrium (Y)), gallium (Ga), magnesium (Mg), such as AlₐO_{b} (1<a, 1<b), SiO_{b1} (1<b1), Nb_{c}O_{b2} (1<c, 1<b2), TiO_{b3} (1<b3) or ZrO_{b3} (1<b4). The low-reflectivity structure has a reflectivity of more than 85% and may include metal oxides, such as Al₂O₃, or metal oxynitrides, such as AlNOₓ. The high-reflectivity structure has a reflectivity of more than 90% and can include, for example, multiple pairs of SiO₂/Ta₂O₅ and include Al₂O₃ and SiO₂ located on both sides of SiO₂/Ta₂O₅.

As shown in FIG. 1B, the contact structure 104 covers and contacts the ridge portion RD of the second semiconductor structure 103 but does not cover and contact the wider portion RW of the second semiconductor structure 103. Similarly, as shown in FIG. 1A, the contact structure 104 is arranged in a rectangle shape extending along the first edge 100c (that is, the long side direction) of the substrate 100. In other words, the contact structure 104 continuously extends from the first end face E1 to the second end face E2. In other words, sidewalls of the contact structure 104 are aligned with the first end face E1 and the second end face E2. The contact structure 104 may partially or completely (not shown) cover the ridge portion RD. As shown in FIGS. 1A and 1B, the ridge portion RD includes sidewalls RDS. The contact structure 104 partially covers the ridge portion RD and is spaced apart from the sidewall RDS of the ridge portion RD by a distance D1. For example, the distance D1 is greater than 0 μm and less than 1.5 μm. In one embodiment, the contact structure 104 may cover beyond the ridge portion RD and contact the wider portion RW. In one embodiment, the contact structure 104 may be separated from the first end face E1 and/or the second end face E2 (not shown) by a distance greater than 5 μm and less than 25 μm.

The contact structure 104 includes metal oxide or metal and is transparent to light emitted by active structure 102. The metal oxide includes indium tin oxide (ITO), zinc oxide (ZnO), zinc indium tin oxide (ZITO), indium zinc oxide (ZIO), zinc tin oxide (ZTO), gallium indium tin oxide (GITO), gallium indium oxide (GIO), gallium zinc oxide (GZO), aluminum-doped zinc oxide (AZO), fluorine doped tin oxide (FTO). The metal includes aluminum (Al), nickel (Ni), gold (Au). When the material of the contact structure 104 includes metal, a thickness of the contact structure 104 is less than 500 angstroms.

The upper electrode structure 107 covers the ridge portion RD and the wider portion RW and contacts the contact structure 104 to form an electrical connection with the epitaxial stack 110. A protective structure 106 is between the upper electrode structure 107 and the ridge portion RD and between the upper electrode structure 107 and the wider portion RW to avoid unnecessary current paths. The intermediate structure 105 is located at the bottom surface 100b of the substrate 100 and contacts the substrate 100. The lower electrode structure 108 contacts the intermediate structure 105 to form an electrical connection with the epitaxial stack 110.

As shown in FIG. 1B, in this embodiment, the intermediate structure 105 includes a first interlayer 1051 and optionally includes a second interlayer 1052. The first interlayer 1051 is located between the substrate 100 and the second interlayer 1052, and the second interlayer 1052 is located between the first interlayer 1051 and the lower electrode structure 108. In this embodiment, the first interlayer 1051 contacts a part of the bottom surface 100b of the substrate 100. In other words, another part of the bottom surface 100b does not contact the first interlayer 1051. In one embodiment, the first interlayer 1051 separates from the first edge 100c of the substrate 100 by a distance of 10 μm˜20 μm. In another embodiment, the first interlayer 1051 contacts with the entire bottom surface 100b of the substrate 100.

In this embodiment, the first interlayer 1051 has a third width W3 and a first sidewall S1, and the second interlayer 1052 has a fourth width W4 and a second sidewall S2. The third width W3 is larger than the fourth width W4. The first sidewall S1 has a first slope, and the second side wall S2 has a second slope substantially equal to the first slope. The lower electrode structure 108 has a fifth width W5 and a third sidewall S3. The third sidewall S3 has a third slope. In this embodiment, the third width W3 or/and the fourth width W4 is greater than the fifth width W5. The third slope is greater than the first slope or/and the second slope. In one embodiment, through a design in which the third width W3 or/and the fourth width W4 is greater than the fifth width W5, the intermediate structure 105 can serve as a barrier to prevent the material in the substrate 100 or the epitaxial stack 110 from diffusing to the lower electrode structure 108, thereby affecting the contact characteristics between the substrate 100 and the lower electrode structure 108. In one embodiment, the lower electrode structure 108 contacts the second sidewall S2 of the second interlayer 1052.

In one embodiment, the intermediate structure 105 includes nitride. In this embodiment, the intermediate structure 105 includes metal and nitrogen or metal nitride. Specifically, the first interlayer 1051 includes the first metal and nitrogen, and its chemical formula is M1ₓ₁N_{y1}, and x1>y1. The second interlayer 1052 includes the second metal and nitrogen, and its chemical formula is M2ₓ₂N_{y2}, and x2 can be greater than, less than, or equal to y2. M1 and M2 are metals, such as titanium (Ti), aluminum (Al), indium (In), or gallium (Ga). N is nitrogen (N). The first metal (M1) and the second metal (M2) may be the same or different. In one embodiment, the first metal and the second metal are the same, that is, the first interlayer 1051 and the second interlayer 1052 have the same elements, such as titanium (Ti) and nitrogen (N). In one embodiment, the first interlayer 1051 and the second interlayer 1052 have the compound with same elements but different compositions. In other words, the first metal and the second metal are the same, and the ratio of metal to nitrogen in the first interlayer 1051 is different from that in the second interlayer 1052. More specifically, the chemical formula of the first interlayer 1051 is Tiₓ₁N_{y1} and the chemical formula of the second interlayer 1052 is Tiₓ₂N_{y2} respectively, but the ratios of Ti and N in first interlayer 1051 and second interlayer 1052 are different. That is, x1/y1≠x2/y2. In one embodiment, the ratio of metal to nitrogen in the first interlayer 1051 is greater than the ratio of metal to nitrogen in the second interlayer 1052. That is, x1/y1>x2/y2. For example, the material of the first interlayer 1051 is Ti₂N and the material of the second interlayer 1052 is TiN. As mentioned above, by forming the first interlayer 1051 and the second interlayer 1052 and adjusting the ratio of metal and nitrogen between the first interlayer 1051 and the second interlayer 1052, the material in the substrate 100 or the epitaxial stack 110 can be prevented from diffusing into the lower electrode structure 108. Therefore, the contact characteristics between lower electrode structure 108 and substrate 100 can avoid deterioration.

The first interlayer 1051 has a first thickness, and the second interlayer has a second thickness. In one embodiment, the first thickness is less than the second thickness. For example, the first thickness is between 1 nm and 50 nm, and the second thickness is between 50 nm and 500 nm. In this embodiment as shown in FIG. 1B, the bottom surface 100b of the substrate 100 of the semiconductor device 20 is a smooth surface.

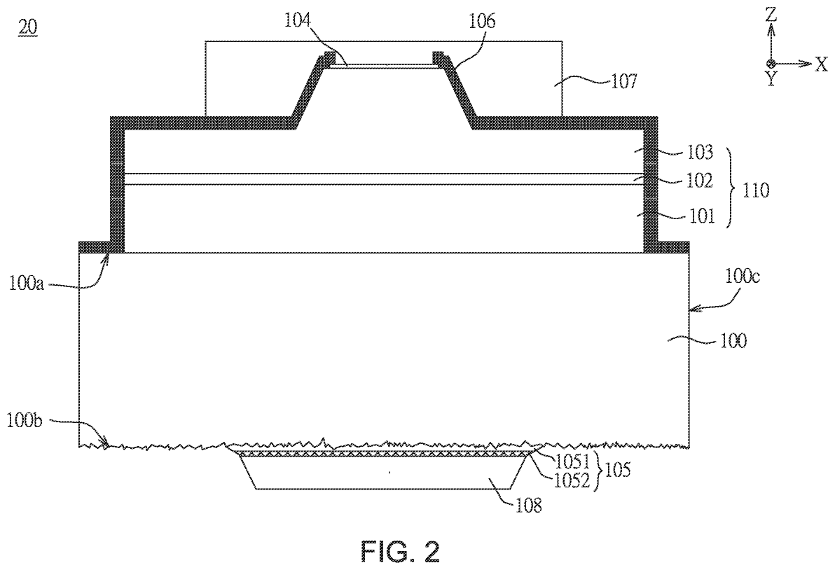

FIG. 2 is a schematic cross-sectional view of a semiconductor device 20 according to an embodiment of the present disclosure. The structure of the semiconductor device 20 is similar with the semiconductor device 10. In this embodiment, the bottom surface 100b of the substrate 100 in the semiconductor device 20 is a rough surface. Thereby, the adhesion between the intermediate structure 105 and the substrate 100 can be increased. The positions, compositions and materials of other layers or structures in this embodiment may be referred to the previous embodiments and will not be described again here.

In some embodiments, the substrate 100 can be silicon substrate, nitrogen-based semiconductor substrate, silicon carbide substrate, gallium arsenide substrate, or indium phosphide substrate. In one embodiment, the substrate 100 is nitrogen-based semiconductor material and can be represented by the general formula InₘAlₙGa₁₋ₘ₋ₙN (0≤m, 0≤n, m+n≤1), such as gallium nitride (GaN). The upper surface 100a of substrate 100 includes (0001) plane, (000-1) plane, (10-10) plane, (11-20) plane, (10-14) plane, (10-15) plane or (11-24) plane. In one embodiment, the upper surface 100a of the substrate 100 is (0001) plane as the epitaxial growth plane of the epitaxial stack 110. In one embodiment, the substrate 100 may include dopant with a doping concentration less than 3×10¹⁸ cm⁻³ and have the same conductive type as the first semiconductor structure 101. The thickness of substrate 100 may be 50 μm˜500 μm.

In some embodiments, the upper electrode structure 107 may be a single layer or multiple layers and include chromium (Cr), aluminum (Al), palladium (Pd), platinum (Pt), nickel (Ni), gold (Au), titanium (Ti), tungsten (W), or alloys of the above. The lower electrode structure 108 may be a single layer or multiple layers and include palladium (Pd), chromium (Cr), titanium (Ti), aluminum (Al), gold (Au), platinum (Pt) or alloys thereof. The protective structure 106 is insulating and may include oxides, nitrides, or oxynitrides of silicon (Si), zirconium (Zr), aluminum (Al), or tantalum (Ta).

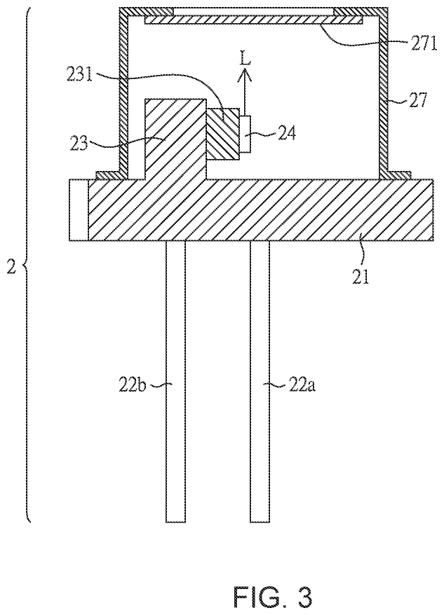

FIG. 3 illustrates a schematic cross-sectional view of a semiconductor apparatus 2 according to an embodiment of the present disclosure. The semiconductor apparatus 2 includes a heat sink 21, first pins 22a, second pins 22b, a fixed base 23, a secondary mounting base 231, a semiconductor device 24 and a metal cover 27. The first pin 22a and the second pin 22b are disposed on a lower surface of the heat sink 21. The fixed base 23 is disposed on a top surface of the heat sink 21 and connected to the second pin 22b of the ground (GND). The secondary mounting base 231 is disposed on one side of the fixed base 23 and is connected to the semiconductor device 24. The metal cover 27 further includes a glass window 271 disposed on its top surface, and the metal cover 27 is joined to the heat sink 21. The semiconductor device 24 may be the semiconductor devices 10, 20 of the embodiments of the present disclosure. When the semiconductor apparatus 2 is connected to an external power source, the semiconductor device 24 can emit a laser light L toward the glass window 271 to leave the semiconductor apparatus 2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising an upper surface and a bottom surface;
an epitaxial stack on the upper surface and comprising an active structure; and
a first interlayer at the bottom surface and comprising M1ₓ₁N_{y1}; wherein M1 is metal and N is nitrogen, and x1>y1.

2. The semiconductor device as claimed in claim 1, further comprising a second interlayer, and the first interlayer is between the epitaxial stack and the second interlayer.

3. The semiconductor device as claimed in claim 1, wherein the second interlayer comprises M1ₓ₂N_{y2}, and x2/y2 is different from x1/y1.

4. The semiconductor device as claimed in claim 3, wherein x1/y1 is larger than x2/y2.

5. The semiconductor device as claimed in claim 2, wherein the first interlayer comprises a first thickness and the second interlayer comprises a second thickness larger than the first thickness.

6. The semiconductor device as claimed in claim 2, wherein the epitaxial stack comprises a ridge portion away from the substrate.

7. The semiconductor device as claimed in claim 1, further comprising a lower electrode structure, and wherein the first interlayer locates between the epitaxial stack and the lower electrode structure.

8. The semiconductor device as claimed in claim 7, wherein the first interlayer comprises a width larger than a width of the lower electrode structure.

9. The semiconductor device as claimed in claim 1, wherein the bottom surface of the substrate is a rough surface.

10. The semiconductor device as claimed in claim 1, wherein M1 is titanium (Ti), aluminum (Al), indium (In), or gallium (Ga).

11. The semiconductor device as claimed in claim 6, further comprising an upper electrode structure on the ridge portion and a contact structure between the ridge portion and the upper electrode structure.

12. The semiconductor device as claimed in claim 11, wherein the ridge portion comprises a sidewall and the contact structure is spaced apart from the sidewall.

13. A semiconductor device, comprising:
a substrate comprising an upper surface and a bottom surface;
an epitaxial stack on the upper surface and comprising an active structure;
a lower electrode structure on the bottom surface; and
a first interlayer between the epitaxial stack and the lower electrode structure;
wherein the first interlayer comprises a width larger than a width of the lower electrode structure.

14. The semiconductor device as claimed in claim 13, wherein the first interlayer comprises M1ₓ₁N_{y1}, and M1 is metal and N is nitrogen, x1>y1.

15. The semiconductor device as claimed in claim 13, further comprising an upper electrode structure on the epitaxial stack, and wherein the substrate and the epitaxial stack are between the upper electrode structure and the lower electrode structure.

16. The semiconductor device as claimed in claim 13, wherein a part of the bottom surface of the substrate does not contact the first interlayer.

17. The semiconductor device as claimed in claim 13, wherein the first interlayer comprises a first sidewall with a first slope and the lower electrode structure comprises a third sidewall with a third slope larger than the first slope.

18. The semiconductor device as claimed in claim 13, further comprising a second interlayer between the first interlayer and the lower electrode structure, and wherein the second interlayer comprises a width larger than the width of the lower electrode structure and smaller than the width of the first interlayer.

19. The semiconductor device as claimed in claim 18, wherein the first interlayer comprises a first sidewall with a first slope and the second interlayer comprises a second sidewall with a second slope equal to the first slope.

20. The semiconductor device as claimed in claim 13, wherein the substrate comprises a first side, and the first interlayer separates from the first side by 10 μm˜20 μm.
